(19) United States
(12) Patent Application Publication
(10) Pub. No.: US 2009/0047749 A1
(43) Pub. Date: Feb. 19, 2009

(54) Methods of manufacturing thin film transistor and display device

(75) Inventors: Han-Tu Lin, Hsin-Chu (TW); Kuo-Yu Huang, Hsin-Chu (TW)

Correspondence Address: BACON & THOMAS, PLLC, 625 SLATERS LANE, FOURTH FLOOR, ALEXANDRIA, VA, 22314-1176, US

(73) Assignee: AU OPTRONICS CORP., Hsin-Chu (TW)

(21) Appl. No.: 12/213,253

(22) Filed: Jun. 17, 2008

(30) Foreign Application Priority Data
Aug. 13, 2007 (TW) 96129895

(51) Int. Cl. H01L 21/336; H01L 33/00

(52) U.S. Cl. 438/29; 438/158; 257/E21.411; 257/E33.001

(57) ABSTRACT

A first patterned conductive layer is formed on a substrate. A dielectric layer, a semiconductor layer, a second conductive layer and a photoresist layer are formed above the first patterned conductive layer. The photoresist layer is patterned using a photomask with multiple different transparencies, and the patterned photoresist layer has at least three different thicknesses. The photoresist layer within the channel region is removed. The second conductive layer within the channel region and part of semiconductor layer are etched to form a channel, source and drain of a thin film transistor. The photoresist layer corresponding to a pixel connecting region and a data pad region is removed to expose a pixel connecting region and a data pad. The remained photoresist layer is reflowed so as to cover the channel. The uncovered semiconductor layer is removed using the reflowed photoresist layer and the patterned second conductive layer as a mask.

This application claims the benefit of Taiwan application Serial No. 096129895, filed Aug. 13, 2007, the subject matter of which is incorporated herein by reference.

### BACKGROUND OF THE INVENTION

1. Field of the Invention

The invention relates in general to methods of manufacturing a thin film transistor and a display device, and more particularly methods of manufacturing a thin film transistor and a display device applied therewith by using a photomask with four different transparencies to reduce the number of photomasks used in the manufacturing method.

2. Description of the Related Art

Conventionally, a method of manufacturing a thin film transistor liquid crystal display (TFT-LCD) requires processes with four or five photomasks. The conventional process includes steps of forming a gate (a first metal layer), a dielectric layer, a semiconductor layer, a source and a drain (a second metal layer), a protection layer, a transparent electrode (for example, ITO), etc. However, in order to simplify the steps and reducing the cost, it is desired to manufacturing LCD product with at least the same quality and efficiency by using less photomasks.

### SUMMARY OF THE INVENTION

The invention is directed to methods of manufacturing a thin film transistor and a display device for reducing the number of photomasks used in the method, and the manufacturing cost is therefore decreased.

According to the present invention, a method of manufacturing a thin film transistor (TFT) is provided. A channel region of the TFT is positioned between a source region and a drain region in a substrate. The method includes following steps. First, a patterned first conductive layer is formed on the substrate, and the patterned first conducive layer includes a gate. Next, a dielectric layer, a semiconductor layer, a second conductive layer and a photoresist layer are sequentially formed over the patterned first conductive layer. Then, a photomask with multiple different light transparencies is provided for exposing and developing the photoresist layer to form a patterned photoresist layer having at least three thicknesses. There is no photoresist within the gate pad region. The patterned photoresist layer corresponding to the channel region, the capacitance region and the pixel region has a first thickness. The patterned photoresist layer corresponding to a pixel connecting region and the data pad region has a second thickness. The patterned photoresist layer corresponding to the source region and the drain region has a third thickness. The third thickness is greater than the second thickness, and the second thickness is greater than the first thickness. Afterwards, the patterned photoresist layer having the first thickness within the channel region is removed. The second conductive layer and part of the semiconductor layer (that is, an n+ a-Si layer) within the channel region are then removed to form a channel, a source and a drain of the TFT. The patterned photoresist layer having the second thickness is removed to expose the pixel connecting region. Subsequently, the remained patterned photoresist layer corresponding to the source, the drain and the surroundings is reflowed by heating, so that the channel is covered by the reflowed photoresist. Next, the uncovered semiconductor layer is removed by using the reflowed photoresist and the patterned second conductive layer as a mask. Then, a patterned transparent electrode is formed to cover the pixel connecting region.

According to the present invention, a method of manufacturing a display device is further provided. The display device includes several scan lines and data lines. The scan lines and the data lines are perpendicular and arranged as an array. Also, the scan lines and the data lines define several pixel regions. Each pixel region is defined by two adjacent scan lines and two adjacent data lines. Each scan line is connected with a gate pad within a gate pad region. Each data line is connected with a data pad within a data pad region. The method includes following steps. First, a patterned first conductive layer is formed on a substrate. The patterned first conductive layer includes data lines, a gate within a TFT region and a capacitance electrode within a capacitance (Cst) region of each pixel region, and the gate pad within each gate pad region. Next, a dielectric layer, a semiconductor layer, a second conductive layer and a photoresist layer are sequentially formed over the substrate and cover the entire substrate. Then, a photomask with four multiple different light transparencies is provided to expose and develop the photoresist layer to form a patterned photoresist layer. The patterned photoresist layer includes (a) the patterned photoresist layer corresponding to a channel region, a Cst region and the pixel region and having a first thickness, the patterned photoresist layer corresponding to a pixel connecting region and a data pad region and having a second thickness, and the patterned photoresist layer corresponding to the source region and the drain region and having a third thickness. The third thickness is greater than the second thickness, and the second thickness is greater than the first thickness. The patterned photoresist layer also includes (b) the patterned photoresist layer over the gate pad within the gate pad region being completely removed, and the patterned photoresist layer corresponding to the surroundings of the gate pad region having the first thickness. Afterwards, the second conductive layer, the semiconductor layer and the dielectric layer within the gate pad region are removed to expose the gate pad. Also, the patterned photoresist layer having the first thickness is removed to expose part of the second conductive layer. Later, the exposed second conductive layer and part of the semiconductor layer (that is, n+ a-Si layer) are removed using the patterned photoresist layer having the second and the third thickness as a mask, so that a channel, a source and a drain within the TFT region, the data lines and the data pads are correspondingly formed. Next, the patterned photoresist layer having the second thickness is removed to expose the pixel connecting region and the data pad region. Subsequently, the remained photoresist layer corresponding to the source region and the drain region is reflowed by heat, so that the channel is covered by the reflowed photoresist layer. The uncovered semiconductor layer is removed using the reflowed photoresist layer and the patterned second conductive layer as a mask. Then, a patterned transparent electrode is formed to cover the pixel connecting region.

The invention will become apparent from the following detailed description of the preferred but non-limiting embodiments. The following description is made with reference to the accompanying drawings.

### BRIEF DESCRIPTION OF THE DRAWINGS

FIG. 1A-FIG. 1J illustrate a method of manufacturing a display device according to a preferred embodiment of the present invention.

### DETAILED DESCRIPTION OF THE INVENTION

A method of manufacturing a thin film transistor for reducing the number of photomasks used in the method is provided in the present invention. A photomask with four different transparencies is used for forming a photoresist pattern having at least three different thicknesses. Also, an organic photoresist which is photosensitive and heat-resistant is used for reducing the number of photomasks. Accordingly, the manufacturing cost is lowered. This method can be applied for manufacturing display devices with different structures, such as a capacitor on gate (COG) structure or a capacitor on common (COC) structure. Also, the thin film transistor (TFT) of the display devices could be a back-channel etching (BCE) type TFT or an etch stop type TFT. The present invention is not limited thereto.

A BCE type TFT is illustrated in the embodiment. It is noted that the embodiment disclosed herein is used for illustrating the present invention, but not for limiting the scope of the present invention. Additionally, the drawings used for illustrating the embodiment and applications of the present invention only show the major characteristic parts in order to avoid obscuring the present invention. Accordingly, the specification and the drawings are to be regard as an illustrative sense rather than a restrictive sense.

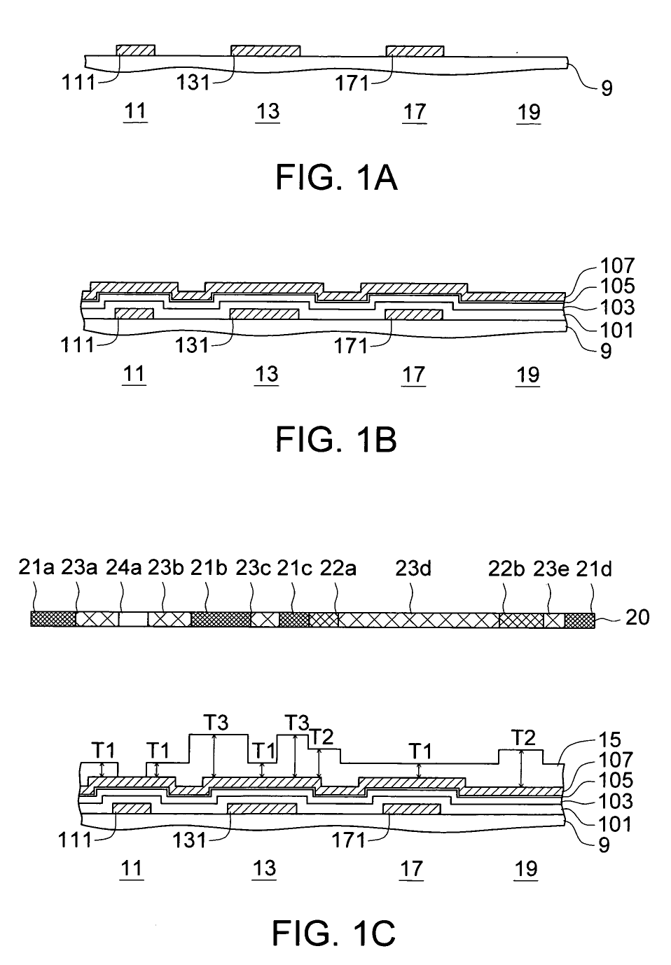

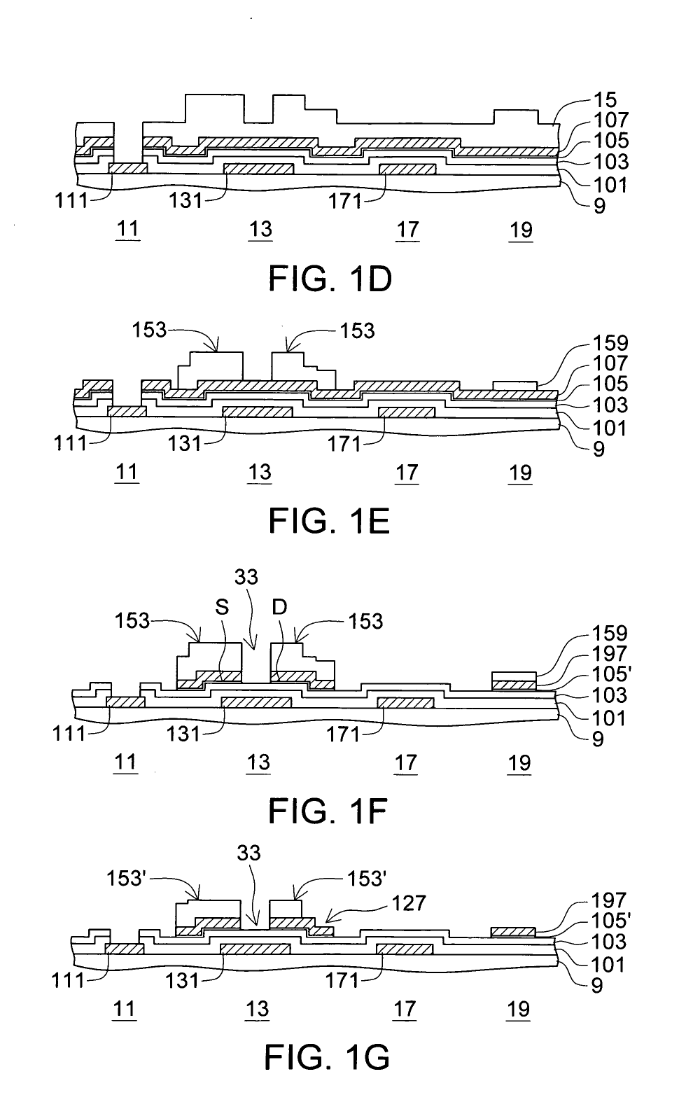

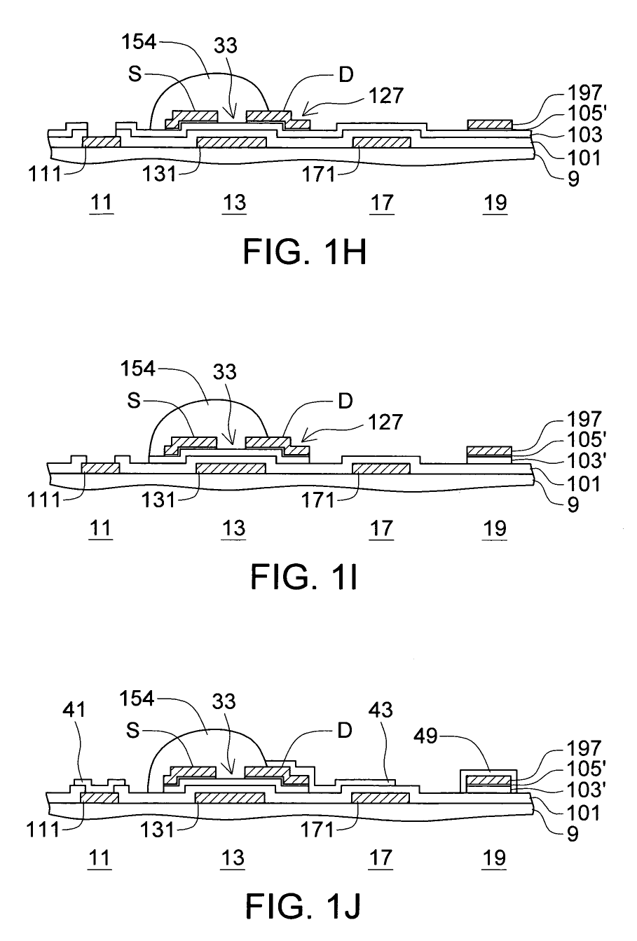

Please refer to FIG. 1A˜FIG. 1J. A method of manufacturing a display device according to the preferred embodiment of the present invention is illustrated in FIG. 1A˜FIG. 1J. The display device includes several scan lines (not shown in the drawings) and several data lines (not shown in the drawings). The scan lines and the data lines are perpendicular and arranged as an array for defining pixels. Each pixel is defined by two adjacent scan lines and two adjacent data lines. In the present embodiment, the substrate includes a plurality of pixel regions, gate pad regions 11 and data pad regions 19, each pixel region includes a TFT region 13 and a capacitance (Cst) region 17 for illustration.

### First Mask Manufacturing Process

First, a first conductive layer, such as a first metal layer (not shown in drawings), is formed on a substrate 9. Next, the first conductive layer is patterned (for example, by a photographic and etching process) to form a gate pad 111, a gate 131 and a capacitance electrode 171 respectively in the gate pad region 11, the TFT region 13 and the Cst region 17 of each pixel, as shown in FIG. 1A.

### Second Mask Manufacturing Process

Next, as shown in FIG. 1B, a dielectric layer (such as a silicon nitride layer 101), and a semiconductor layer are formed over the substrate 9 sequentially. The semiconductor layer includes an amorphous silicon (a-Si) layer 103 and an n-type doped amorphous silicon (n+ a-Si) layer 105. Then, a second conductive layer such as a second metal layer 107 is formed on the n+ a-Si layer 105. The silicon nitride layer 101 covers the gate pad 111, the gate 131 and the capacitance electrode 171 on the substrate 9.

Afterward, a photoresist layer is formed over the second metal layer 107. A photomask 20 with multiple different light transparencies, such as four different light transparencies, is provided for exposing and developing the photoresist layer. The photomask 20 of the present embodiment includes several first light-penetrable regions 21a, 21b, 21c and 21d, second light-penetrable regions 22a and 22b, third light-penetrable regions 23a, 23b, 23c and 23d, and a fourth transparent region 24a. The light transparencies of the first light-penetrable regions, the second light-penetrable regions, the third light-penetrable regions and the fourth light-penetrable region are in ascending order. Moreover, the photoresist layer is a positive photoresist layer and preferably made of an organic material, which is etch resistant and can be reflowed at a high temperature.

After development, a patterned photoresist layer 15 with three different thicknesses is formed, as shown in FIG. 1C. The patterned photoresist layer 15 of FIG. 1C includes several parts, and illustrated below.

(a) There are three different photoresist thicknesses (T1, T2 and T3) presented in the TFT region 13. The patterned photoresist layer within a channel region of the TFT region 13 has a first thickness T1. The patterned photoresist layer within a pixel connecting region (marked as 127 in FIG. 1G) adjacent to the drain region has a second thickness T2. The patterned photoresist layer within the source region and drain region has a third thickness T3. The third thickness T3 is greater than the second thickness T2. The second thickness T2 is greater than the first thickness T1.

(b) In the gate pad region 11, the photoresist layer over the gate pad 111 is removed, and the patterned photoresist layer corresponding to the surroundings of the gate pad 111 has the first thickness T1.

(c) The patterned photoresist layer within the Cst region 17 has the first thickness T1.

(d) The patterned photoresist layer within the data pad region 19 has the second thickness T2.

Next, as shown in FIG. 1D, the second metal layer 107, the n+ a-Si layer 105, the a-Si layer 103 and the silicon nitride layer 101 within the gate pad region 11 are sequentially removed by dry etching to expose the gate pad 111.

Subsequently, the photoresist layer 15 is thinned by dry etching or ashing for reducing the thickness of the photoresist layer 15. The thinned photoresist pattern is shown in FIG. 1E and includes the following parts.

(1) The photoresist layer 15 corresponding to the channel region in the TFT region 13 has been removed. The patterned photoresist layer 15 within the source region and drain region has been thinned (photoresist block 153 in FIG. 1E).

(2) The photoresist layer 15 in the gate pad region 11 and the Cst region 17 has been removed.

(3) The patterned photoresist layer 15 corresponding to the data pad region 19 has been thinned (the photoresist block 159 in FIG. 1E).

Afterwards, according to the photoresist block 153 in the TFT region 13, the second metal layer 107 and the n+ a-Si layer 105 in the channel region are etched (for example, by wet-etching) to form a channel 33, a source S and a drain D in the TFT region 13, as shown in FIG. 1F. When this step is performed, the second metal layer 107 and the n+ a-Si layer 105 in the gate pad region 11 and the Cst region 17 could be removed simultaneously. Accordingly, a data pad 197 is formed in the data pad region 19 by using the photoresist block 159 as a mask.

Then, as shown in FIG. 1G, the thickness of the photoresist block 153 in the TFT region 13 is reduced (thinned) again to form the photoresist block 153′. After thinned, the photoresist block 153′ corresponding to the source region and drain region and the surroundings thereof exposes the patterned second conductive layer in the pixel connecting region 127 adjacent to the drain D. The thinning step could be performed by etching or ashing. When the photoresist block 153 is thinned, the photoresist block 159 within the data pad region 19 could also be removed simultaneously to expose the data pad 197.

Later, the remained photoresist block 153′ corresponding to the source region and drain region and the surroundings thereof is reflowed by heating, and the channel 33 is filled with and covered by the reflowed photoresist layer 154. As shown in FIG. 1H, the reflowed photoresist layer 154 covers the channel 33 and protects the source S/drain D (formed by the patterned second metal layer 107). Additionally, before performing the step of heating the photoresist, the channel 33 is preferably subjected to a plasma treatment for improving the electrical properties of the TFT.

Next, as shown in FIG. 1I, the uncovered portions of the semiconductor layer (the a-Si layer 103) is removed by using the reflowed photoresist layer 154 and the patterned second conductive layer (the second metal layer 107) as a mask. Only the silicon nitride layer 101 is remained in the gate pad region 11 and the Cst region 17. A stack structure including the data pad 197, the patterned n+ a-Si layer 105′ and the patterned a-Si layer 103′ is formed in the data pad region 19. The structure shown in FIG. 1I is obtained after performing the second photomask manufacturing process according to the preferred embodiment of the present invention.

### Third Mask Manufacturing Process

Then, a transparent conductive layer, such as an ITO layer, is formed on the silicon nitride layer 101. Through a patterning process, a transparent electrode 43 is formed on the pixel region including the pixel connecting region 127 and the capacitor region 17. The transparent electrode 43 is electrically connected to the drain D through the pixel connecting region. Also, a transparent electrode 41 is formed on the gate pad 111 within the gate pad region 11, and a transparent electrode 49 is formed on the data pad 197 within the data pad region 19, as shown in FIG. 1J. The transparent electrode 49 in the data pad region 19 covers the stacked structure including the data pad 197, the patterned n+ a-Si layer 105′ and the patterned a-Si layer 103′.

According to aforementioned description, the photomask with four different transparencies of the embodiment is used for forming a photoresist pattern with three different thicknesses. The reflowed photoresist 154 can be used as a protection layer in the display device, so there is no need to form another protection layer in the subsequent procedures. Therefore, the number of photomasks used in the manufacturing method is reduced, and the manufacturing cost is decreased as well.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method of manufacturing a thin film transistor (TFT) on a substrate, the method comprising:
forming a patterned first conductive layer on the substrate, the patterned first conductive layer comprising a gate;
sequentially forming a dielectric layer, a semiconductor layer, a second conductive layer and a photoresist layer over the patterned first conductive layer and the substrate;
patterning the photoresist layer to form a patterned photoresist layer having at least three thicknesses by utilizing a photomask with multiple light transparencies, wherein the patterned photoresist layer within a channel region has a first thickness, the patterned photoresist layer in a pixel connecting region has a second thickness, the patterned photoresist layer corresponding to a source region and a drain region has a third thickness, the third thickness is greater than the second thickness, and the second thickness is greater than the first thickness;
removing the patterned photoresist layer having the first thickness within the channel region;
etching the second conductive layer and part of the semiconductor layer within the channel region to form a channel, a source and a drain of the TFT;
removing the patterned photoresist layer having the second thickness to expose the pixel connecting region;
heating the patterned photoresist layer corresponding to the source region and the drain region to form a reflowed photoresist layer covering the source, the drain and the channel;
removing uncovered semiconductor layer by using the reflowed photoresist layer and the patterned second conductive layer as a mask; and
forming a patterned transparent electrode electrically connected to the drain through the pixel connecting region.

2. The method according to claim 1, wherein the step of forming the gate comprises:
forming a first metal layer on the substrate; and
patterning the first metal layer to form the gate.

3. The method according to claim 1, wherein the semiconductor layer comprises an amorphous silicon layer.

4. The method according to claim 3, further comprising forming an n type doped amorphous silicon layer over the amorphous silicon layer.

5. The method according to claim 1, wherein the patterned photoresist layer having the first thickness within the channel region is removed by dry etching or ashing, and the second conductive layer within the channel region is removed by wet etching.

6. The method according to claim 1, wherein the patterned photoresist layer having the second thickness is removed by etching or ashing.

7. The method according to claim 1 further comprising:
applying a plasma treatment to the channel before performing the step of heating the patterned photoresist layer.

8. The method according to claim 1, wherein a material of the photoresist layer comprises an organic material.

9. The method according to claim 1, wherein the dielectric layer comprises a silicon nitride layer, and the transparent electrode comprises an indium tin oxide layer.

10. A method of manufacturing a display device on a substrate, the substrate having a plurality of pixel regions, a plurality gate pad regions and a plurality of data pad regions, the method comprising:
forming a first patterned conductive layer on the substrate, the patterned first conductive layer comprising a plurality of gate lines, a gate within a TFT region and a capacitance electrode within a capacitance region of each pixel region, and gate pads in the gate pad regions;
sequentially forming a dielectric layer, a semiconductor layer, a second conductive layer and a photoresist layer for covering the entire substrate;
patterning the photoresist layer to form a patterned photoresist layer having at least three thicknesses by utilizing a photomask with four different light transparencies, the patterned photoresist layer comprising: (a) the patterned photoresist layer having a first thickness within a channel region in the TFT region, the patterned photoresist having a second thickness within a pixel connecting region and, the patterned photoresist layer having a third thickness corresponding to the source region and the drain region, wherein the third thickness is greater than the second thickness, and the second thickness is greater than the first thickness, (b) the patterned photoresist layer over the gate pads within the gate pad regions being removed;
sequentially removing the second conductive layer, the semiconductor layer and the dielectric layer within the gate pad region to expose the gate pad;
removing the patterned photoresist having the first thickness to expose part of the second conductive layer;
removing the exposed second conductive layer and part of the semiconductor layer using the patterned photoresist layer having the second thickness and the third thickness as a mask to form a patterned second conductive layer including a channel, a source and a drain within the each TFT region, the data lines and data pads in the data pad regions, removing the patterned photoresist having the second thickness to expos the pixel connecting region;
heating the patterned photoresist corresponding to the source region and the drain region to form a reflowed photoresist layer covering the channel, the source and the drain;
removing uncovered semiconductor layer using the reflowed photoresist layer and the patterned second conductive layer as a mask; and
forming a patterned transparent electrode electrically connected to the drain through the pixel connecting region.

11. The method according to claim 10, wherein the gate, the capacitance electrode and the gate pad are formed by forming a first metal layer on the substrate followed by patterning the first metal layer.

12. The method according to claim 10, wherein the semiconductor layer comprises an amorphous silicon layer.

13. The method according to claim 12, further comprising forming an n type doped amorphous silicon layer on the amorphous silicon layer.

14. The method according to claim 13, wherein the step of removing the exposed second conductive layer and part of the semiconductor layer comprises:
etching the second conductive layer and the n type doped amorphous silicon layer.

15. The method according to claim 10, wherein in the step of patterning the photoresist layer, the patterned photoresist layer further comprises:
(c) the patterned photoresist layer having the first thickness in the Cst region.

16. The method according to claim 10, wherein the patterned photoresist within the channel region of the TFT region is removed by dry etching or ashing, the second conductive layer within the channel region is removed by wet etching.

17. The method according to claim 10, wherein the step of removing the patterned photoresist having the first thickness comprises removing the patterned photoresist layer within the gate pad region and the Cst region by dry etching or ashing.

18. The method according to claim 10, wherein the patterned photoresist layer corresponding to the source region and the drain region of the TFT region is thinned by etching or ashing.

19. The method according to claim 10 further comprising: applying a plasma treatment to the channel within the TFT region before performing the step of heating the patterned photoresist layer.

20. The method according to claim 10, wherein in the step of forming the patterned transparent electrode, the patterned transparent electrode further cover the gate pad within the gate pad region.

21. The method according to claim 10, wherein in the step of patterning the photoresist layer, the patterned photoresist layer further comprises:
(d) the patterned photoresist layer having the second thickness within the data pad regions.

22. The method according to claim 21, wherein in the step of removing the pattern photoresist layer having the second thickness, the pattern photoresist layer within the data pad regions is also removed to expose the data pads.

23. The method according to claim 22, wherein in the step of forming the patterned transparent electrode, the patterned transparent electrode further cover the data pads within the data pad regions.

24. The method according to claim 10, wherein a material of the photoresist layer comprises an organic material.

25. The method according to claim 10, wherein the dielectric layer comprises a silicon nitride layer, and the transparent electrode comprises an ITO layer.
